(19) United States
(12) Patent Application Publication
(10) Pub. No.: US 2017/0317059 A1
(43) Pub. Date: Nov. 2, 2017

(54) ELECTRONIC DEVICE WITH ELECTRONIC CHIPS AND HEAT SINK

(71) Applicant: STMicroelectronics (Grenoble 2) SAS, Grenoble (FR)

(72) Inventors: Benoit Besancon, Villard Bonnot (FR); Norbert Chevrier, Lumbin (FR); Jean-Michel Riviere, Froges (FR)

(73) Assignee: STMicroelectronics (Grenoble 2) SAS, Grenoble (FR)

(21) Appl. No.: 15/364,452

(22) Filed: Nov. 30, 2016

(30) Foreign Application Priority Data
May 2, 2016 (FR) 1653948

(51) Int. Cl. H01L 25/065; H01L 23/367

(52) U.S. Cl. CPC H01L 25/0657; H01L 23/367; H01L 2225/06582; H01L 2225/06517; H01L 2225/06589; H01L 2225/06558

(57) ABSTRACT

An electronic device includes a first support platelet and a second support platelet that is disposed opposite and at a distance from the first support platelet. At least one first electronic chip is mounted on the first support platelet on a side facing the second support platelet. A second electronic chip is mounted on the second support platelet on a side facing the first support platelet. A heat sink that includes at least one interposition plate is interposed between the first and second electronic chips.

### PRIORITY CLAIM

This application claims priority from French application for Patent No. 1653948 filed May 2, 2016, the disclosure of which is hereby incorporated by reference.

### TECHNICAL FIELD

The present invention relates to the field of electronic devices that include electronic chips.

### BACKGROUND

In electronic devices that include electronic chips with increased data processing and computation powers, the removal of the heat produced is a challenge.

### SUMMARY

In order to respond to this challenge, an electronic device is provided which includes a first support platelet; a second support platelet, which lies opposite and at a distance from the first support platelet; at least one first electronic chip, which is mounted on the first support platelet on the side facing the second support platelet; a second electronic chip, which is mounted on the second support platelet on the side facing the first support platelet; and a heat sink, which comprises at least one interposition plate interposed between the said first and second electronic chips.

Electrical connection elements may be interposed between the first and second support platelets, in which case these electrical connection elements may be at a distance from the electronic chips and the heat sink.

The said chips may at least partly face one another.

The said chips may be offset, the said interposition plate being in the shape of staircase steps, one of the chips may be on one of the steps and the other chip may be on the opposite face of the other step.

The first support platelet may be provided with a first electrical connection network. The second support platelet may be provided with a second electrical connection network.

The first electronic chip may be mounted on the first support platelet by means of electrical connection elements which are connected to the said first electrical connection network.

The second electronic chip may be mounted on the second support platelet by means of electrical connection elements which are connected to the said second electrical connection network.

Electrical connection elements may be interposed between the first and second support platelets and are connected to the said first and second electrical connection networks.

The heat sink may comprise at least one external plate carried by at least one of the said first and second support platelets.

The heat sink may comprise vias passing through at least one of the said first and second support platelets.

At least one other electronic chip may be mounted on the other face of at least one of the said first and second support platelets.

The heat sink may comprise at least one plate extending above this other chip.

At least one encapsulation block may be formed at least between the said first and second support platelets.

The heat sink may be at least partly embodied in this encapsulation block.

The heat sink may comprise at least one external plate carried by the said encapsulation block.

The heat sink may comprise at least one external radiator.

One of the said support platelets may be provided with external electrical connection elements, of which at least some may be connected to the heat sink.

### BRIEF DESCRIPTION OF THE DRAWINGS

Electronic devices will now be described by way of nonlimiting examples which are illustrated by the appended drawing, in which:

FIG. 1 represents a section of one electronic device;

FIG. 2 represents a section of another electronic device;

FIG. 3 represents a section of another electronic device; and

FIG. 4 represents a section of another electronic device.

### DETAILED DESCRIPTION OF THE DRAWINGS

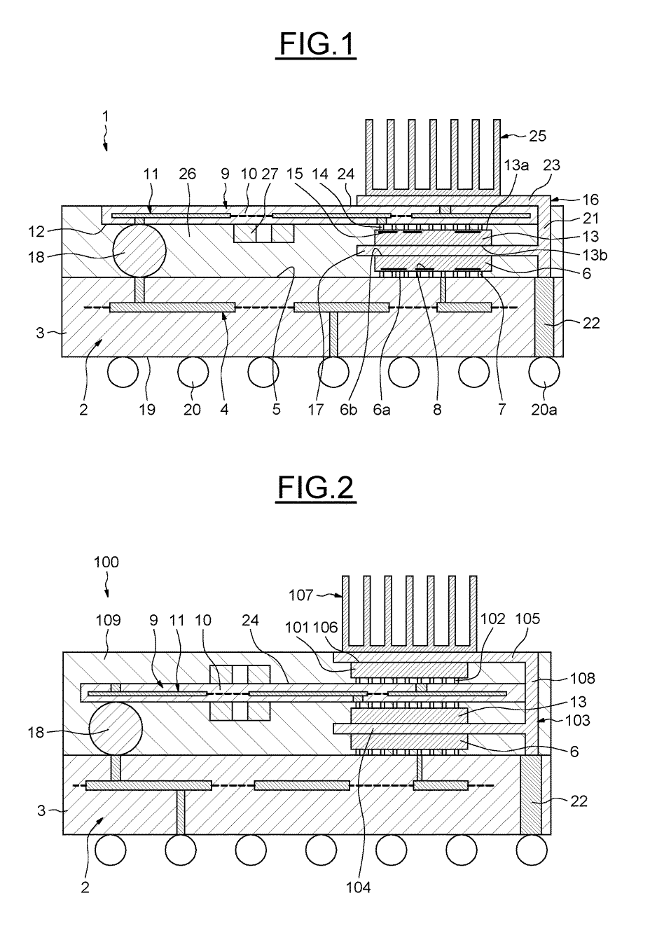

According to one exemplary embodiment, which is illustrated in FIG. 1, an electronic device 1 comprises a first assembly 2, which comprises a first support platelet 3 provided with an integrated electrical connection network 4 which, above a face 5, carries a first electronic chip 6 by means of electrical connection elements 7 which are interposed between the face 5 of the first support platelet 3 and a front face 6a of the chip 6. The interposed electrical connection elements 7 connect the electrical connection network 4 and an internal electrical connection network 8 of the first chip 5.

The electronic device 1 comprises a second assembly 9, which comprises a second support platelet 10 provided with an integrated electrical connection network 11 which, above a face 12, carries a second electronic chip 13 by means of electrical connection elements 14 which are interposed between the face 12 of the second support platelet 10 and a front face 13a of the chip 13. The interposed electrical connection elements 14 connect the electrical connection network 11 of the second support platelet 10 and an internal electrical connection network 15 of the second chip 13.

The assemblies 2 and 9 are stacked and arranged with respect to one another in the following way.

The first support platelet 3 and the second support platelet 10 are arranged parallel to and at a distance from one another, with their faces 5 and 12 facing one another. The first chip 6 is on the side of the second support platelet 10. The second chip 13 is on the side of the first support platelet 3. The second support platelet 10 is smaller in area than the first support platelet 3.

The assemblies 2 and 9 are located in such a way that the rear faces 6b and 13b of the chips 6 and 13 face away from the support platelets 3 and 10 and are disposed at a distance perpendicularly to these support platelets 3 and 10. According to the example illustrated in FIG. 1, the rear faces 6b and 13b of the chips 6 and 13 face one another.

The electronic device 1 furthermore comprises a heat sink 16 for dissipating the heat produced by one and/or the other of the chips 6 and 13, this heat sink being made of one or more thermally conductive materials.

The heat sink 16 comprises an interposition plate 17, which extends parallel to the support platelets 3 and 10 and is interposed between the rear faces 6b and 13b of the chips 6 and 13.

The rear faces 6b and 13b of the chips 6 and 13 are in contact with the opposing faces of the plate 17, directly or via a layer of thermal paste or thermal adhesive.

The electronic device 1 comprises inter-platelet electrical connection elements 18, for example balls, interposed between the faces 5 and 12 of the support platelets 3 and 10 and connected to the electrical connection networks 4 and 11 of these support platelets 3 and 10. The electrical connection elements 18 are placed laterally at a distance from the edges of the chips 6 and 13 and of the plate 17 of the heat sink 16.

The electrical connection elements 18 have a thickness matched to the distance between the support platelets 3 and 10, this distance being determined by the combined thicknesses of the chips 6 and 13, of the plate 17 and of the electrical connection elements 7 and 14.

The support platelet 3 is provided on its outer face 19, on the opposite side from its face 5, with external electrical connection elements 20 which are connected to the electrical connection network 4, with a view to electrical connection to an external electronic device.

Thus, the supply of electricity to the first chip 6 can be carried out via the electrical connection network 4 and the electrical connection elements 20; the supply of electricity to the second chip 13 can be carried out via the electrical connection network 4, the electrical connection network 11, the electrical connection elements 18 and the electrical connection elements 20; and electrical signal exchanges between the chip 4 and the external electronic device can be carried out via the electrical connection network 4, and the electrical connection elements 20; electrical signal exchanges between the chip 13 and the external electronic device can be carried out via the electrical connection network 4, the electrical connection network 11, the electrical connection elements 18 and the electrical connection elements 20; and electrical signal exchanges between the chip 13 and the external device can be carried out via the electrical connection network 4, the electrical connection network 11 and the electrical connection elements 20.

The heat sink 16 furthermore comprises extensions for directing the heat produced by one or both of the chips 6 and 13 to the outside of the electronic device 1.

To this end, the heat sink 16 may comprise a plate 21, or plate portions, attached to or integral with an edge of the plate 17 and arranged perpendicularly to the plate 17. The plate 21 extends as far as the face 5 of the support platelet 3. Thermally conductive vias 22 are provided through the support platelet 3 and are on the one hand in contact, directly or via a layer of thermal paste or thermal adhesive, with an edge of the plate 21 and on the other hand in contact with connection elements 20a which are identical to the electrical connection elements 20, with a view to connection of heat exchanges to the aforementioned external device.

With a view to heating exchanges with the ambient environment, the heat sink 16 may comprise an external plate 23 which is in contact, directly or via a layer of thermal paste or thermal adhesive, with the external face 24 of the support platelet 10, on the opposite side from its face 12. The plate 21 is extended as far as the plate 23, while passing close to an edge of the support platelet 10, and is in contact with the plate 23, directly or via a layer of thermal paste or thermal adhesive.

Provided above the plate 23, there may be an external finned radiator 25 which is mounted by means of a layer of thermal paste or thermal adhesive.

According to one alternative embodiment, the plate 17 and the plate 21 could be in one piece.

According to another alternative embodiment, the plate 21 and the plate 23 could be in one piece.

According to another alternative embodiment, the plate 17 and the portion of the plate 21 extending to the support platelet 3 could be in one piece. The plate 17 and the portion of the plate 21 extending to the plate 23 could be in one piece.

According to another alternative embodiment, the plate 17 and/or the plate 21 and/or the plate 23 could be in several parts, for example formed by parallel lamellae, and/or could be perforated.

According to another alternative embodiment, the plate 21 could be replaced at least in part by thermal struts interposed, for example, on the one hand between the plate 17 and the vias 22 and/or on the other hand between the plate 17 and the plate 23.

According to another alternative embodiment, the chips 6 and 13 could be offset along the plate 17. For example, the chips 6 and 13 might not be located facing one another. In this case, the plate 17 could be formed as staircase steps, one of the chips being on one of the steps and the other chip being on the opposite face of the other step. Thus, the distance between the support platelets 3 and 10 could be reduced, which would allow the thickness of the electrical connection elements 18, for example the diameter of the balls forming these elements, and the thickness of the electronic device 1 to also be reduced.

According to another alternative embodiment, the support platelet 3 and/or the support platelet 10 could be provided with other electronic chips, which are mounted in an equivalent way to the chips 6 and 13 and are also in contact, directly or via a layer of thermal paste or thermal adhesive, above the faces of the plate 17 of the heat sink 16.

The heat sink 16 and the vias 22 may be metallic, for example made of copper.

Furthermore, the electronic device 1 comprises an encapsulation block 26, which is formed in particular between the support platelets 3 and 10 and in which the chips 6 and 13, the electrical connection elements 18, and at least partially the plate 17, are embedded.

According to the example represented, the plate 17 and the plate 21 are embedded in the encapsulation block 26, and the latter encloses the support platelet 10 and covers the entire surface 5 of the support platelet 3, so that the electronic device 1 is in the form of a parallelepipedal. The support platelet 10 could, however, be embedded in the encapsulation block 26, the plate 23 then being above or flush-fitted into this encapsulation block.

The support platelet 3 and/or the support platelet 10 could optionally be provided with discrete electronic components 27 and/or other electronic chips, without contact with the plate 17 of the heat sink 16, for example above their faces 5 and 12, these components 27 and these other chips being embedded in the encapsulation block 26.

According to another exemplary embodiment, which is illustrated in FIG. 2, an electronic device 100 comprises, in an equivalent way to the example described with reference to FIG. 1, a first assembly 2 which comprises a support platelet 3 and an electronic chip 6, and a second assembly 9, which comprises a support platelet 10 and an electronic chip 13.

The assembly 9 is furthermore provided with a third electronic chip 101, which is mounted above the face 24 of the support platelet 10 by means of electrical connection elements 102 which are connected to the electrical connection network 11 of the support platelet 10, with a view to its electricity supply and exchanges of electrical signals.

The electronic device 100 comprises a heat sink 103, which comprises a plate 104 that is equivalent to the plate 17 of the heat sink 16 and extends between the chips 6 and 13.

The heat sink 103 comprises a plate 105, which extends above the face 106 of the chip 101 on the opposite side from the electrical connection elements 102 and is in contact, directly or via a layer of thermal paste or thermal adhesive, and an external radiator 107 installed above the plate 105.

The heat sink 103 comprises a plate 108 which is equivalent to the plate 21 of the heat sink 16 and is connected to the vias 22 of the support platelet 3, to the plate 104 and to the plate 105.

The electronic device 100 comprises an encapsulation block 109, which is equivalent to the encapsulation block 26 of the electronic device 1 but differs therefrom in that, this time, the support platelet 10 and the chip 101 are embedded in this encapsulation block 109, in which case the plate 105 may be flush-fitted into this encapsulation block 109.

The electronic device 100 may also be of parallelepipedal shape.

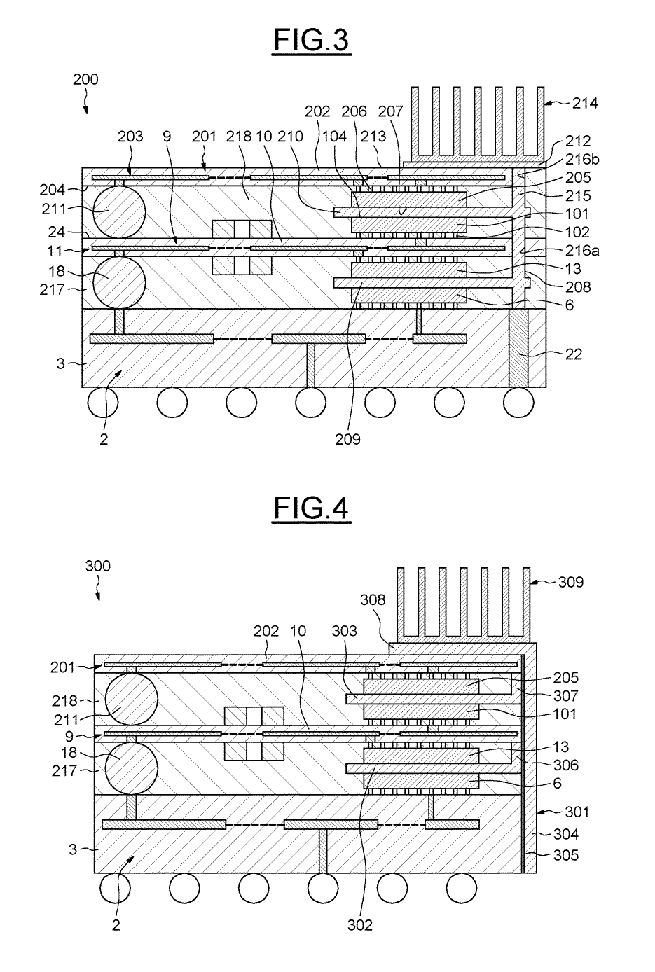

According to another exemplary embodiment, which is illustrated in FIG. 3, an electronic device 200 comprises, in an equivalent way to the example described with reference to FIG. 2, a first assembly 2 which comprises a support platelet 3 and an electronic chip 6, and a second assembly 9 which comprises a support platelet 10, an electronic chip 13 and an electronic chip 101.

This time, however, the support platelets 3 and 10 have the same area and cover one another.

The electronic device 200 furthermore comprises a third assembly 201, which comprises a support platelet 202 provided with an integrated electrical connection network 203 and fitted, above a face 204, with a fourth electronic chip 205 by means of electrical connection elements 206 which are connected to the electrical connection network 203.

The third assembly 201 is stacked above the assembly 9, in a way equivalent to the stacking of the assembly 9 on the assembly 2 and in the following way.

The third support platelet 202 is arranged parallel to and at a distance from the second support platelet 10, with their faces 204 and 24 facing one another. The third chip 101 is on the side of the third support platelet 202. The fourth chip 205 is on the side of the second support platelet 10.

The assemblies 9 and 201 are located in such a way that the rear faces 24 and 207 of the chips 101 and 205 are at a distance perpendicularly to the support platelets 3 and 10. As illustrated in FIG. 3, the rear faces 24 and 207 of the chips 101 and 205 may face one another.

The support platelets 10 and 202 have the same area and cover one another.

The electronic device 200 is equipped with a heat sink 208 which, as before, comprises a plate 209 interposed between the chips 6 and 13.

The heat sink 208 furthermore comprises a plate 210 which extends parallel to the support platelets 10 and 202 and passes between the chips 101 and 205.

The rear faces 104 and 207 of the chips 101 and 205 are in contact, directly or via a layer of thermal paste or thermal adhesive, with the opposing faces of the plate 210.

The electronic device 200 comprises inter-platelet electrical connection elements 211, for example balls, which are interposed between the faces 24 and 204 of the support platelets 10 and 202 and are connected to the electrical connection networks 11 and 203 of these support platelets 10 and 202.

The electrical connection elements 211 have a thickness matched to the distance between the support platelets 10 and 202, this distance being determined by the thicknesses of the chips 101 and 205, of the plate 210 and of the electrical connection elements 102 and 206.

The heat sink 208 comprises a plate 212 placed on the external face 213 of the support platelet 202, on the opposite side from its face 204, which is equivalent to the aforementioned plate 23. A radiator 214 is installed on the plate 212.

The heat sink 208 comprises a plate 215, which is equivalent to the aforementioned plates 21 and 108.

This time, the plate 215 extends through the passages 216a and 216b of the support platelets 10 and 202 in order to be connected on the one hand to the vias 22 of the support platelet 3 and on the other hand to the plate 212.

Edges of the plates 209 and 210 are connected laterally to the plate 215.

The electronic device 200 comprises an encapsulation block 217 which fills the space between the support platelets 3 and 10, and an encapsulation block 218 which fills the space between the support platelets 10 and 202, so that the electronic device 200 can also be in the form of a parallelepipedal.

According to another exemplary embodiment, which is illustrated in FIG. 4, an electronic device 300 comprises the assemblies 2, 9 and 201 of the electronic device 200 described with reference to FIG. 3, and a heat sink 301 which comprises plates 302 and 303 that extend respectively between the chips 6 and 13 and between the chips 101 and 205.

The heat sink 301 comprises a lateral external plate 304, which at least partially covers corresponding edges of the support platelets 3, 10 and 202 and of the encapsulation blocks 217 and 218 and is fixed, for example by means of a layer of thermal adhesive 305, in which case the plate 304 may optionally be flush-fitted.

The plates 302 and 303 comprise side-edges 306 and 307 at right angles, which are in contact with the inner face of the plate 304, directly or via the layer of thermal adhesive 305.

The heat sink 301 comprises a plate 308, which is equivalent to the plate 212, connected to the plate 304 and fitted with an external radiator 309.

In this example illustrated in FIG. 4, the vias 22 of the preceding examples may be omitted.

It follows from the description above that electronic devices may be formed by a stack of an arbitrary plurality of assemblies, each comprising a support platelet carrying electronic chips above its opposing faces, the support platelets being located at least partly facing one another, that the support platelets may be connected by electrical connection elements, and that a heat sink may comprise interposition plates respectively interposed between the chips carried by two adjacent support platelets.

In such a stack, the support platelet forming one of the ends of the stack advantageously does not have an external chip, but is provided with external electrical connection elements, whereas the support platelet forming the other end of the stack may optionally be provided with at least one chip and may be provided with a radiator.

What is claimed is:

1. An electronic device, comprising
a first support platelet;
a second support platelet disposed opposite and at a distance from the first support platelet;
a first electronic chip mounted on the first support platelet on a side facing the second support platelet;
a second electronic chip mounted on the second support platelet on a side facing the first support platelet; and
a heat sink comprising at least one interposition plate interposed between the first and second electronic chips.

2. The electronic device according to claim 1, further comprising a plurality of electrical connection elements interposed between the first and second support platelets at a distance from the first and the second electronic chips and the heat sink.

3. The electronic device according to claim 1, wherein the first electronic chip at least partially faces the second electronic chip.

4. The electronic device according to claim 1, wherein the first electronic chip is offset from the second electronic chip and the said interposition plate being step-shaped, one of the first or second electronic chips being disposed on a first step portion of the interposition plate and the other electronic chip being disposed on an opposite face of a second step portion of the interposition plate.

5. The electronic device according to claim 1, wherein:
the first support platelet includes a first electrical connection network;
the second support platelet includes a second electrical connection network;
the first electronic chip is mounted on the first support platelet by a first plurality of electrical connection elements connected to the first electrical connection network;
the second electronic chip is mounted on the second support platelet by a second plurality of electrical connection elements connected to the second electrical connection network; and
a third plurality of electrical connection elements interposed between the first and second support platelets and connected to the first and second electrical connection networks.

6. The electronic device to claim 1, wherein the heat sink comprises at least one external plate carried by at least one of the first and second support platelets.

7. The electronic device according to claim 1, wherein the heat sink comprises thermally conductive vias passing through at least one of the first and second support platelets.

8. The electronic device according to claim 1, wherein the first electronic chip is mounted on a first face of the first support platelet and the second electronic chip is mounted on a second face of the second support platelet and further comprising a third electronic chip mounted on a third face of the first support platelet opposite the first face or a fourth face of the second support platelet opposite the second face, wherein the heat sink comprises at least one plate extending above the third electronic chip.

9. The electronic device according to claim 1, further comprising at least one encapsulation block formed at least between the said first and second support platelets, the heat sink being at least partly encapsulated in the encapsulation block.

10. The electronic device according to claim 9, wherein the heat sink comprises at least one external plate carried by the encapsulation block.

11. The electronic device according to claim 1, wherein the heat sink comprises at least one external radiator.

12. The electronic device according to claim 1, wherein at least one of the first and second support platelets includes external electrical connection elements, at least some of the external electrical connection elements being connected to the heat sink.

13. An electronic device, comprising
a first support platelet;
a second support platelet disposed opposite and at a distance from the first support platelet;
a first electronic chip mounted on the first support platelet on a side facing the second support platelet;
a second electronic chip mounted on the second support platelet on a side facing the first support platelet; and
a heat sink comprising at least one interposition plate interposed between the first and second electronic chips, the interposition plate disposed in thermal contact with a first rear face of the first electronic chip and a second rear face of the second electronic chip.

14. The electronic device to claim 13, wherein the heat sink comprises at least one external plate carried by at least one of the first and second support platelets.

15. The electronic device according to claim 13, wherein the first electronic chip is mounted on a first face of the first support platelet and the second electronic chip is mounted on a second face of the second support platelet and further comprising a third electronic chip mounted on a third face of the first support platelet opposite the first face or a fourth face of the second support platelet opposite the second face, wherein the heat sink comprises at least one plate extending above the third electronic chip.

16. The electronic device according to claim 13, further comprising at least one encapsulation block formed at least between the first and second support platelets, the heat sink being at least partly encapsulated in the encapsulation block.

17. The electronic device according to claim 16, wherein the heat sink comprises at least one external plate carried by the encapsulation block.

18. The electronic device according to claim 13, wherein the heat sink comprises at least one external radiator.

19. An electronic device, comprising
a first support platelet;
a second support platelet disposed opposite and at a distance from the first support platelet;
a first electronic chip mounted on the first support platelet on a side facing the second support platelet;
a second electronic chip mounted on the second support platelet on a side facing the first support platelet;
a heat sink comprising at least one interposition plate interposed between the first and second electronic chips, the interposition plate disposed in thermal contact with a first rear face of the first electronic chip and a second rear face of the second electronic chip; and
at least one encapsulation block formed at least between the said first and second support platelets, the heat sink being at least partly encapsulated in the encapsulation block.

20. The electronic device to claim 19, wherein the heat sink comprises at least one external plate carried by at least one of the first and second support platelets.
